(19) United States
(12) Patent Application Publication
(10) Pub. No.: US 2025/0005253 A1
(43) Pub. Date: Jan. 2, 2025

(54) FIELD-PROGRAMMABLE GATE ARRAY (FPGA) MODULAR IMPLEMENTATION

(71) Applicant: Synopsys, Inc., Sunnyvale, CA (US)

(72) Inventors: Jitendra Kumar GUPTA, San Diego, CA (US); Tobias SIMON, Ilmenau (DE); Matthias MUELLER, Erfurt (DE); Joseph C. MARCENO, Pleasanton, CA (US)

(21) Appl. No.: 18/215,133

(22) Filed: Jun. 27, 2023

(51) Int. Cl. G06F 30/398

(52) U.S. Cl. CPC G06F 30/398

(57) ABSTRACT

Certain aspects of the present disclosure are directed towards a method for circuit equivalence processing. The method generally includes: receiving a circuit design including a plurality of subsystems, each of the plurality of subsystems being implemented using at least one field-programmable gate array (FPGA); analyzing, via one or more processors, the plurality of subsystems for equivalence to identify at least two subsystems of the plurality of subsystems to be replaced with at least two replicated subsystems; and generating a netlist for the circuit design including the at least two replicated subsystems.

### TECHNICAL FIELD

The present disclosure generally relates to a hardware-assisted verification system, and more particularly, to modular implementation for a field-programmable gate array (FPGA) system.

### BACKGROUND

A field-programmable gate array (FPGA) is a reconfigurable integrated circuit that can be programmed to perform specific computing tasks. In other words, unlike other application specific integrated circuits (ASICs) that are designed to provide a specific function, FPGAs can be reconfigured to serve various functions. An FPGA includes an array of configurable logic blocks and programmable interconnects. An FPGA may be configured using hardware description language (HDL) or any graphical design tool. FPGAs are used in a wide array of applications, including digital signal processing, embedded systems, or to facilitate rapid prototyping of circuit designs.

### SUMMARY

The following presents a simplified summary of one or more aspects of the present disclosure, in order to provide a basic understanding of such aspects. This summary is not an extensive overview of all contemplated features of the disclosure, and is intended neither to identify key or critical elements of all aspects of the disclosure nor to delineate the scope of any or all aspects of the disclosure. Its sole purpose is to present some concepts of one or more aspects of the disclosure in a simplified form as a prelude to the more detailed description that is presented later.

Certain aspects of the present disclosure are directed towards a method for circuit equivalence processing. The method generally includes: receiving a circuit design including a plurality of subsystems, each of the plurality of subsystems being implemented using at least one field-programmable gate array (FPGA); analyzing, via one or more processors, the plurality of subsystems for equivalence to identify at least two subsystems of the plurality of subsystems to be replaced with at least two replicated subsystems; and generating a netlist for the circuit design including the at least two replicated subsystems.

Certain aspects of the present disclosure are directed towards a method for replicated subsystem generation. The method generally includes: receiving a circuit design including a plurality of subsystems, each of the plurality of subsystems being implemented using at least one FPGA; determining that at least two subsystems of the plurality of subsystems are not equivalent; generating at least two replicated subsystems to replace the at least two subsystems, each of the at least two replicated subsystems being configured to serve circuit functions of the at least two subsystems; and generating a netlist for the circuit design including the at least two replicated subsystems.

Certain aspects of the present disclosure are directed towards a system including a memory storing instructions and a processor, coupled with the memory and to execute the instructions, the instructions when executed cause the processor to: receive a circuit design including a plurality of subsystems, each of the plurality of subsystems being implemented using at least one FPGA; analyze the plurality of subsystems for equivalence to identify at least two subsystems of the plurality of subsystems to be replaced with at least two replicated subsystems; and generate a netlist for the circuit design including the at least two replicated subsystems.

### BRIEF DESCRIPTION OF THE DRAWINGS

The disclosure will be understood more fully from the detailed description given below and from the accompanying figures of embodiments of the disclosure. The figures are used to provide knowledge and understanding of embodiments of the disclosure and do not limit the scope of the disclosure to these specific embodiments. Furthermore, the figures are not necessarily drawn to scale.

FIG. 1 is a graph illustrating increase in prototype development effort as a function of design size.

FIG. 2 is a circuit design analyzed as an aggregate of subsystems, in accordance with certain aspects of the present disclosure.

FIG. 3 illustrates turnaround time associated with parallel processing of subsystems, in accordance with certain aspects of the present disclosure.

FIG. 4A illustrates single-cell subsystems, in accordance with certain aspects of the present disclosure.

FIG. 4B illustrates non-replicated subsystems, in accordance with certain aspects of the present disclosure.

FIG. 4C illustrates a replicated subsystem with multiple design nodes assigned to each subsystem copy, in accordance with certain aspects of the present disclosure.

FIG. 5 illustrates subsystems replaced with replicated subsystems, in accordance with certain aspects of the present disclosure.

FIG. 6A is a flow diagram illustrating example operations for establishing or creating subsystem equivalence, in accordance with certain aspects of the present disclosure.

FIG. 6B illustrates the assignment of subsystems to various buckets, in accordance with certain aspects of the present disclosure.

FIG. 6C illustrates multiple sub-buckets including subsystems, in accordance with certain aspects of the present disclosure.

FIGS. 7A and 7B illustrate graphs used to perform a subsystem equivalence check using graph-isomorphism, in accordance with certain aspects of the present disclosure.

FIG. 8A illustrates subsystem that are partially matched using graph-isomorphism, in accordance with certain aspects of the present disclosure.

FIG. 8B is a table describing equivalence tasks and results performed for subsystems, in accordance with certain aspects of the present disclosure.

FIG. 8C illustrates unmatched logic represented as two clusters, in accordance with certain aspects of the present disclosure.

FIGS. 9A and 9B illustrate an outcome of design repair wherein one subsystem is a proper subset of another subsystem, in accordance with certain aspects of the present disclosure.

FIGS. 10A and 10B illustrate an outcome of design repair where functionality of one subsystem partially overlaps with functionality of another subsystem, in accordance with certain aspects of the present disclosure.

FIGS. 11A and 11B illustrate subsystems with little to no overlap, in accordance with certain aspects of the present disclosure.

FIG. 12 is a flow diagram illustrating example operations for circuit equivalence processing, in accordance with certain aspects of the present disclosure.

FIG. 13 is a flow diagram illustrating example operations for circuit equivalence processing using design repair, in accordance with certain aspects of the present disclosure.

FIG. 14 illustrates an example set of processes used during the design, verification, and fabrication of an article of manufacture.

FIG. 15 illustrates an example machine of a computer system.

FIG. 16 depicts a diagram of an example emulation environment

### DETAILED DESCRIPTION

Certain aspects of the present disclosure are directed towards techniques for identifying field-programmable gate array (FPGA) subsystems in a design circuit that have equivalent circuit structure or functionality. That is, a design circuit may include a design of an electronic system having multiple subsystems (e.g., multiple circuit instances that are parts of the overall design of the electronic system). By identifying equivalent subsystems, the effort to process the subsystems (e.g., to generate associated netlists) may be reduced, as described in more detail herein. Certain subsystems may be similar but not identical. In some aspects of the present disclosure, such similar subsystems may be identified, and replicated subsystems may be generated to replace those similar subsystems, as described in more detail herein. In this manner, the number of replicated subsystems in a design circuit may be increased. Thus, certain aspects provide one or more advantages, including the reduction of turnaround time (TAT) associated with processing circuit designs (e.g., generating a netlist and performing place-and-route (PAR) tasks).

In hardware-assisted verification (HAV), FPGA devices may be used to develop a hardware-prototype of an electronic circuit design. These FPGA-based prototypes may be used for verification of a hardware design as well as the software that runs on such a design to test that the design and software are functioning correctly and meeting specifications.

Electronic development teams use FPGA platforms to validate large system-on-chip (SOC), graphic processing units (GPU), or similar circuit designs. Since the capacity of each FPGA device may be limited, some circuit designs may use many (e.g., 10's to 100's) of FPGA devices to realize the full design prototype. For example, a user may build a prototype of a large circuit design that may fit on a total of 100 FPGA devices and operate at a specific target frequency. The user may partition the circuit design into multiple FPGAs and physically implement the circuit design on the FPGAs after partitioning. For instance, the user may partition the circuit design into 100 parts and assign each part to a specific FPGA such that each circuit design part assigned to an FPGA fills the FPGA device to an acceptable level (e.g., also referred to as the fill-rate or bin-utilization of the FPGA). The FPGAs may be connected to each other so that FPGAs can transfer data to each other at a desired speed, and hence, achieve target performance goals for the overall prototype. The effort involved in design partitioning is a direct function of the size of the design. In many cases, the effort involved in partitioning a large design increases exponentially to the design's size as measured by the number of FPGA devices used.

As described, another task includes the physical implementation of the design on each FPGA. For each design part assigned to an FPGA, the user may synthesize the design netlist, which translates the design from a high-level register-transfer level (RTL) format to an FPGA-friendly netlist format. The user may also use FPGA place-and-route (PAR) tools to generate FPGA bit-files that program each device to implement functionality corresponding to the design part that the FPGA implements. Engineer effort and compute effort involved in implementing the design are linear to the number of FPGAs used.

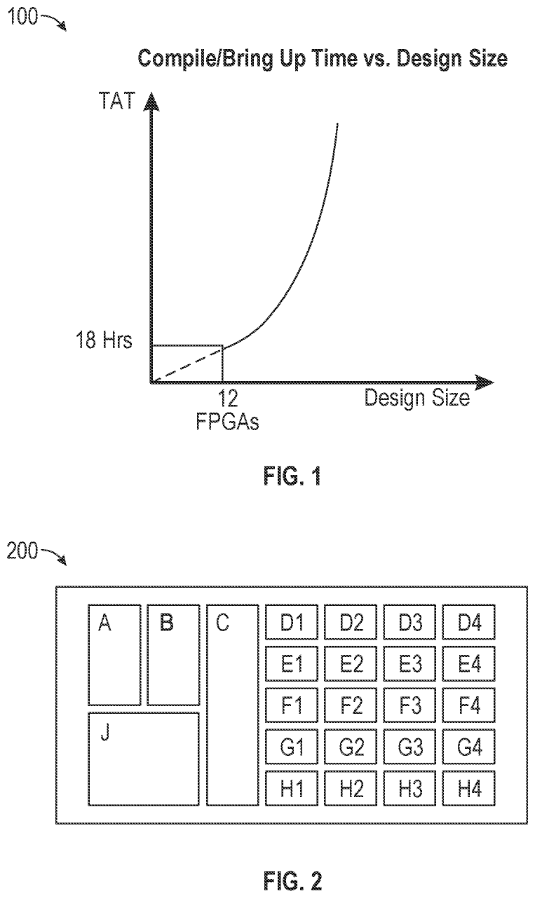

FIG. 1 is a graph 100 illustrating the increase in prototype development effort as a function of design size. Prototype designs are increasing in size at a faster rate than compute capacity. Larger designs (e.g., 50 FPGAs or larger) strain tool capacity and increase complexity. More FPGAs to be implemented means more manual intervention to achieve timing convergence during partition, synthesis, and PAR phases, increasing bring-up time to several days. Each FPGA also involves many synthesis and PAR computation jobs to provide a functional and routable bit file. Any RTL change may result in the entire implementation cycle being repeated. To reduce complexity associated with a large design, the large design may be processed as an aggregate of smaller designs called subsystems (SS).

FIG. 2 is a circuit design 200 analyzed as an aggregate of 24 subsystems. Subsystems A and B may include 10 FPGAs each (a total of 20 FPGAs). Subsystem C may include 15 FPGAs, subsystem J may include 15 FPGAs, and each of subsystems D, E, F, G, and H may include 2 FPGAs each (a total of 40 FPGAs). Subsystems D1, D2, D3, and D4 may be replicated subsystems, as described in more detail herein. As used herein, replicated subsystems refer to subsystems having the same circuit structure.

The technique of developing electrical devices as an aggregate of smaller designs may be referred to as modular flow. Modular flow enables a less complex and more efficient method for prototype development. Each subsystem in the modular flow may be implemented in parallel, reducing tool capacity and runtime and speeding up partition convergence and PAR closure.

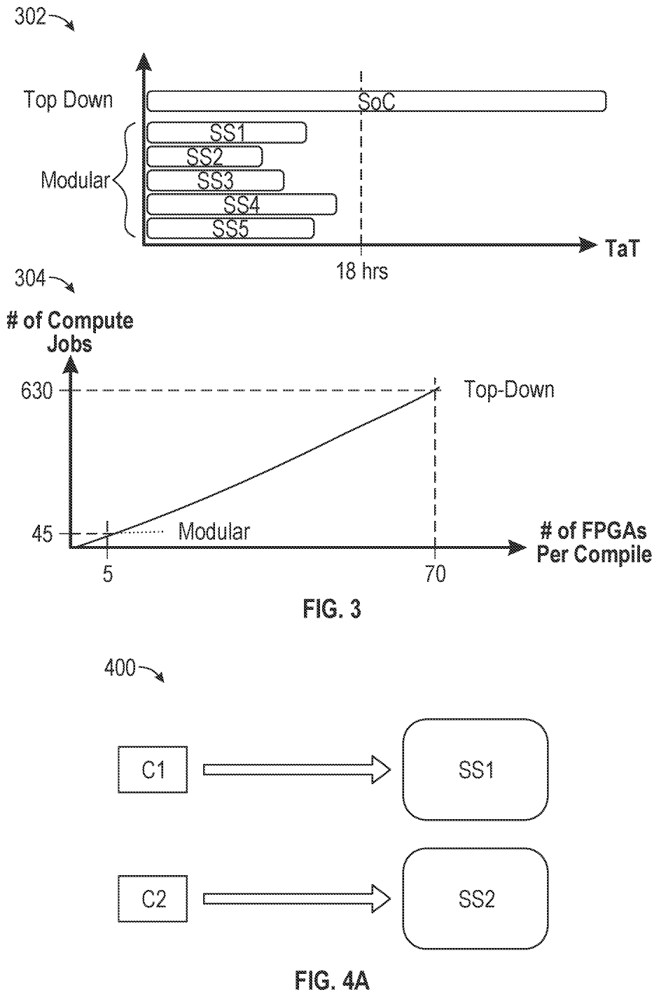

FIG. 3 illustrates TAT associated with parallel processing of subsystems. For example, as shown by diagram 302, subsystems 1-5 (labeled “SS1”, “SS2”, “SS3”, “SS4”, and “SS5”) may be processed in parallel, allowing a turnaround time (TAT) of 18 hours, as one example. Moreover, as shown by graph 304, as the number of FPGAs increases per compile, the number of compute jobs increases linearly. As an example, assume a maximum of 100 partition nodes, 100 FPGAs to implement, and 9 subsystem projects of size: 10, 10, 15, 15, 2, 2, 2, 2 and 2 (e.g., a total of 60 FPGAs). Certain aspects of the present disclosure describe how to implement 40 FPGAs in a manner that allows for the reuse of processing results from one or more of the 60 FPGAs that are implemented. Thus, the largest subsystem to implement may be 15 FPGAs instead of 100 FPGAs. Per-FPGA, computation resources involved may include (N synthesis jobs×M P&R jobs, N and M being positive integers. Thus, from a top-down perspective, 100 FPGAs×3 synthesis jobs×3 PAR jobs may be used, resulting in 900 jobs. When implemented in a modular fashion, 60 FPGAs×3 synthesis jobs×3 PAR jobs may be used, resulting in 540 jobs (360 job reduction). The examples provided do not include tasks related to tool improvement.

In modular flow, there are two key advantages, selective rebuild and FPGA bitfile replication. For rebuild, when an input design changes, only prototypes affected by the design change may have to be implemented again. For example, if a design change is limited to subsystem A, only subsystem A (e.g., having 10 FPGAs) may be implemented again, while the remaining subsystems can be reused from the previous implementation. This reduces the effort involved for the second iteration of the design from 100 FPGAs in top-down implementation to 10 FPGAs during rebuild. For FPGA bitfile replication, the user may implement only one copy of identical subsystem instances and reuse the implementation for other copies. In FIG. 2 for example, subsystem D1 having two FPGAs is implemented once, and the bit files for subsystem D1 is used for D2, D3 and D4 as well, reducing the effort involved for subsystem D from 8 FPGAs in top-down implementation to 2 FPGAs.

In modular flow, correct handling of replicated subsystems is important because generated bit files should be identical to function correctly for each copy of replicated subsystems. This involves internal design and interface logic to other subsystems to be the same across all copies of a replicated subsystem. In some cases, a replicated subsystem may implemented by assigning one identical design node to each copy of the subsystem, otherwise referred to as a single-cell subsystem.

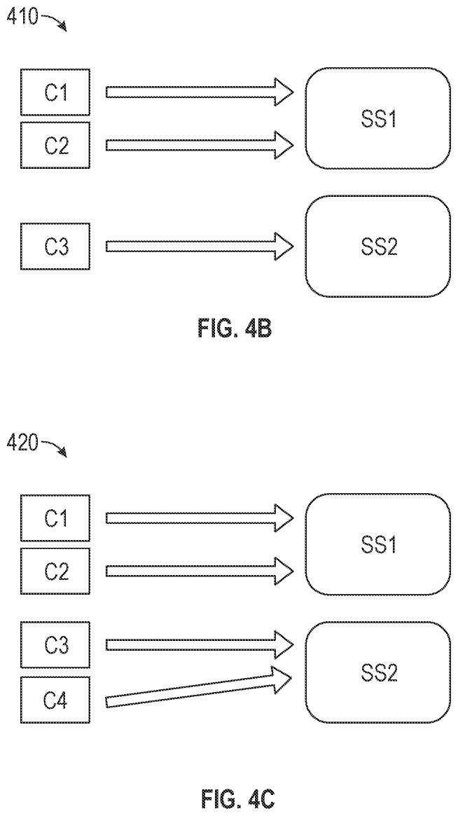

FIG. 4A illustrates a circuit design 400 having single-cell subsystems. For example, design node C1 is assigned to subsystem SS1, and design node C2 is assigned to subsystem SS2. Hence, if design nodes C1 and C2 have the same underlying description (e.g., circuit description such as an adder of a particular type), then SS1 and SS2 can be considered replicated subsystems.

FIG. 4B illustrates a circuit design 410 having non-replicated subsystems. A non-replicated subsystem is implemented by assigning multiple design nodes to a subsystem (e.g., also referred to as a multi-cell subsystem). As shown, design node C1 and design node C2 are assigned to subsystem SS1 (e.g., a multi-cell subsystem), and design node C3 is assigned to subsystem SS2 (e.g., a single-cell subsystem). Thus, subsystems SS1 and SS2 are non-replicated subsystems.

FIG. 4C illustrates a circuit design 420 having a replicated subsystem with multiple design nodes assigned to each subsystem copy. This may be referred to as a multi-cell replicated subsystem. As shown, design node C1 and design node C2 are assigned to subsystem SS1 (e.g., a first copy of a replicated multi-cell subsystem), and design node C3 and design node C4 are assigned to subsystem SS2 (e.g., a second copy of a replicated multi-cell subsystem). Thus, if design node C3 and design node C4 are identical to design node C1 and design node C2, respectively, then subsystems SS1 and SS2 may be considered replicated subsystems. Certain aspects are directed to establishing subsystem equivalence, as described in more detail herein.

A repeated subsystem may refer to a subsystem with multiple similar design nodes assigned to each copy of a subsystem. This subsystem is referred to as repeated subsystems instead of replicated subsystems because the design nodes assigned are similar but not identical, and hence, existing technology may not be able to implement repeated subsystems. Certain aspects of the present disclosure provide techniques to repair the design and hence, convert similar designs to identical designs, increasing the benefit of modular flow, and in case of multicore CPU, GPU or artificial intelligence (AI) designs, reducing the number of unique FPGA implementations by a large factor.

The benefits of modular flow with subsystem replication to a user depend on the design structure (e.g., how the overall design is partitioned into different subsystems and the replication observed across subsystems). Replication across subsystems depends on both techniques involved to facilitate replication across multi-cell subsystems and techniques to perform design repair and enhance subsystem replication.

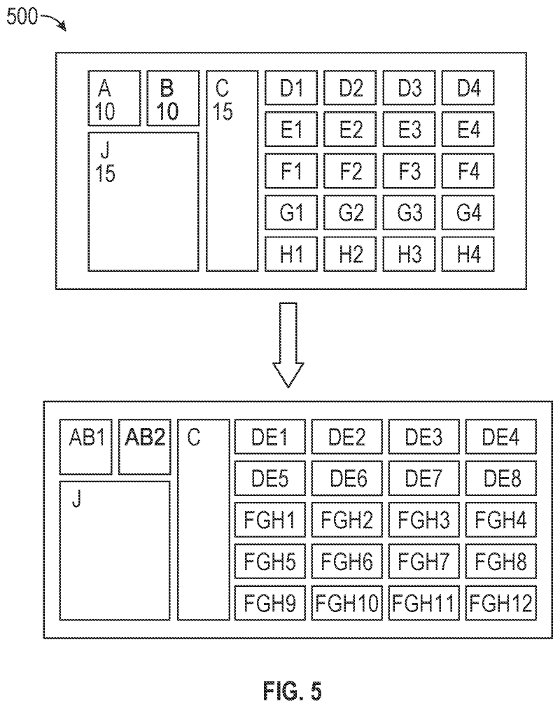

FIG. 5 illustrates a circuit design 500 having subsystems replaced with replicated subsystems, in accordance with certain aspects of the present disclosure. As shown, subsystems A and B (each implemented with 10 FPGAs) may be identified to be equivalent and replaced with replicated subsystems AB1 and AB2. As used herein, circuit instances or subsystems being equivalent generally refers to the instances or subsystems having the same circuit structure, or having different circuit structure, but serving the same logic function. Subsystem AB1 may be a replica of subsystem AB2 and used to replace subsystems A and B, respectively. Similarly, subsystems D1 to D4 and E1 to E4 may be replaced with replicated DE1 to DE8, as shown. Subsystems F1 to F4, G1 to G4, and H1 to H4 may be replaced with replicated subsystems FGH1 to FGH12, as shown. By using the replicated subsystems, the effort as a number of FPGAs to implement a full build may be reduced (e.g., from 90 FPGAs to 60 FPGAs if design repair is not used or 44 FPGAs if design repair is used).

Moreover, subsystems D1 to D4 may be equivalent, and subsystems E1 to E4 may be equivalent. Moreover, the subsystems D1 and E1 may be repaired to be equivalents using design repair as described in more detail herein. Thus, subsystems D1, D2, D3, D4, E1, E2, E3, and E4 may be each replaced with replicated subsystems DE1 to DE8, as shown.

Certain aspects of the present disclosure are directed to techniques and systems to enhance the subsystem replication realized during the modular implementation flow for designs. While example techniques are described in the context of the FPGA prototype implementation to facilitate understanding, the aspects of the present disclosure are not limited to prototyping implementations. For example, described techniques may be applied to emulation and application-specific integrated circuit (ASIC) implementations.

Enhancing subsystem replication is a benefit as it reduces the total number of unique subsystems (e.g., number of non-replicated subsystems) to be implemented to realize the full design. Fewer unique subsystems to implement means reduced engineering effort, reduced compute effort, and lower schedule risk to achieve a functional prototype. Subsystem replication involves establishing subsystem equivalence within parameters that allows FPGA bit files of any one such subsystem to be used to realize all other instances of the replicated subsystem. These parameters may include matching subsystem boundary interfaces (e.g., interconnects through which the subsystem logic communicates with other subsystems and external circuitry) and matching the internal functionality of the subsystems (e.g., the subsystem circuit implements equivalent logic in all copies of the equivalent subsystem). However, an equivalence parameter may generally relax timing and performance specifications. For example, different copies of a replicated subsystem may operate at different clock frequencies. Hence, replication specifications may be implemented for a common implementation to support all target frequencies, from the lowest supported frequency to the highest supported frequency. For instance, if a subsystem P supports a first frequency range (FR1) and a subsystem Q supports a second frequency range (FR2), then a replicated subsystem to replace subsystems P and Q may be configured to support a range of frequencies including FR1 and FR2.

The techniques described herein may be classified into several categories. One example category includes subsystem equivalence at the design graph level, which can be established by graph-isomorphism (GI) techniques. This technique establishes one-to-one correspondence between design objects in a main subsystem (e.g., which is used for implementation) and all equivalent subsystems that may use a common implementation. This one-to-one correspondence is important when implementing inter-subsystem connectivity since subsystem boundary ports may not follow the same name or order, as an example. For ease of understanding, using GI techniques for checking equivalence may be referred to as “SS_EQ_CHECK_GI” techniques.

Another category may include a subsystem equivalence that does not exist at the design graph level (e.g., SS_EQ_CHECK_GI did not identify equivalence), but exists at an electrical or logical level. In other words, a subsystem equivalence may not exist at the design graph level if a circuit description of graph nodes (e.g., circuit instances) of the subsystems or graph edges (e.g., connectivity) of the subsystems are different. Thus, logic equivalence (LE) techniques may be used to establish subsystem equivalence and establish one-to-one object correspondence where applicable. For instance, based on LE, it may be determined that two subsystems serve the same function, and thus, are equivalent in effect. A simple example of such a case is a design circuit, which implements given logic by a multiplexer in one case versus AND/OR gates in another case. Using LE to check for subsystem equivalence may be referred to as “SS_EQ_CHECK_LE.” While some example techniques described herein involve performing SS_EQ_CHECK_GI prior to performing SS_EQ_CHECK_LE, any order of equivalence check may be performed. In some cases, equivalence check may be performed using only SS_EQ_CHECK_LE (or only SS_EQ_CHECK_GI).

In some cases, subsystem equivalence may not exist (e.g., is not identified using SS_EQ_CHECK_LE or SS_EQ_CHECK_GI. Certain aspects of the present disclosure provide design repair techniques to create subsystem equivalence. The design repair techniques evaluate the cost (e.g., measured in terms of design size increase) associated with each successful repair, and when such cost is within bounds established either heuristically by software application or as specified by a user, the repair system applies such design repair to create a repaired subsystem corresponding to one or more of the original subsystems. The repaired subsystem may now serve as a replicated subsystem to replace the original subsystem. For ease of understanding, the design repair technique may be referred to as an “SS_EQ_REPAIR.” Because of targeted design repairs, these repaired subsystems may be expected to demonstrate subsystem equivalence by either SS_EQ_CHECK_GI or SS_EQ_CHECK_LE techniques.

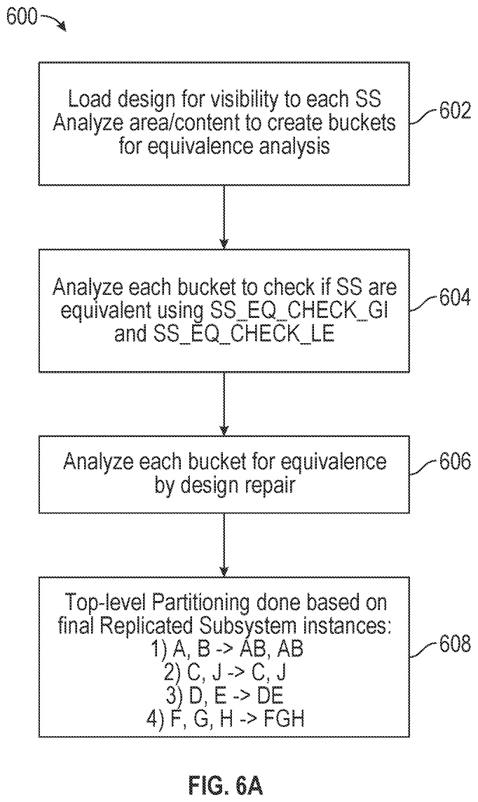

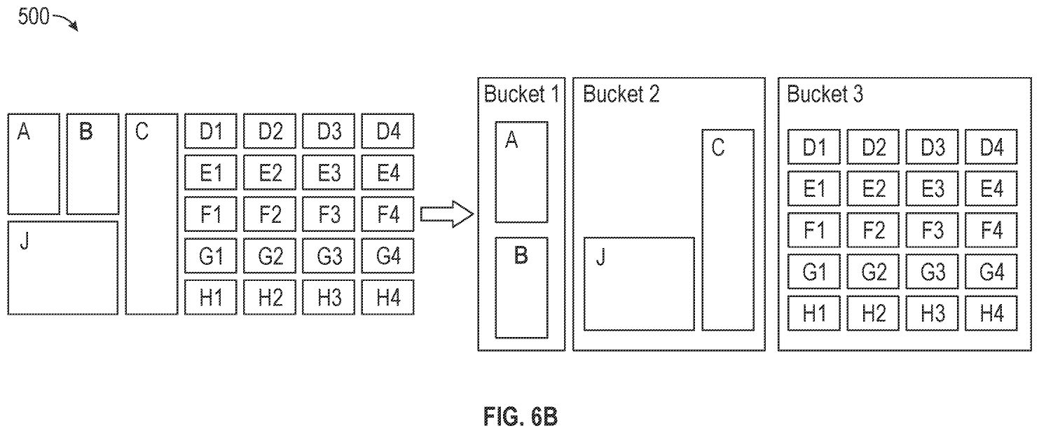

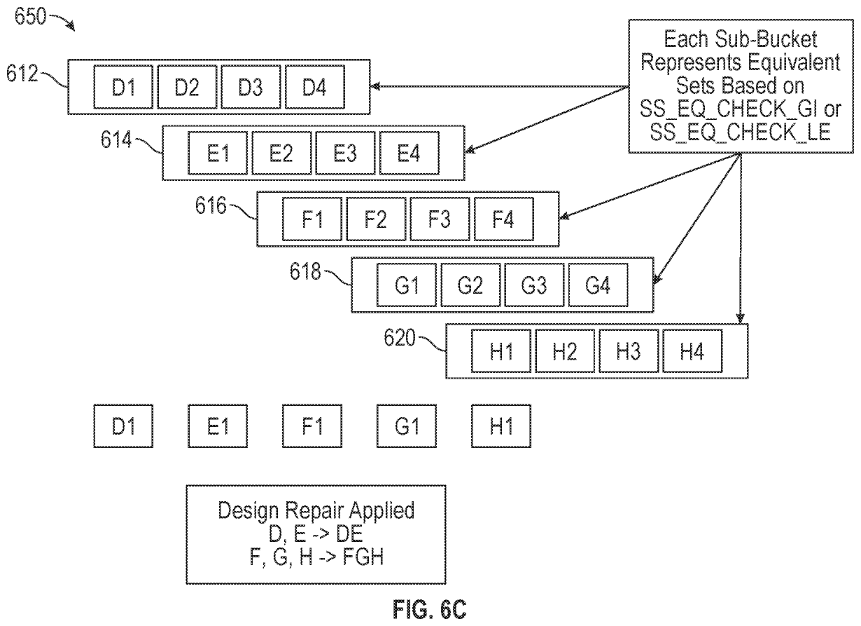

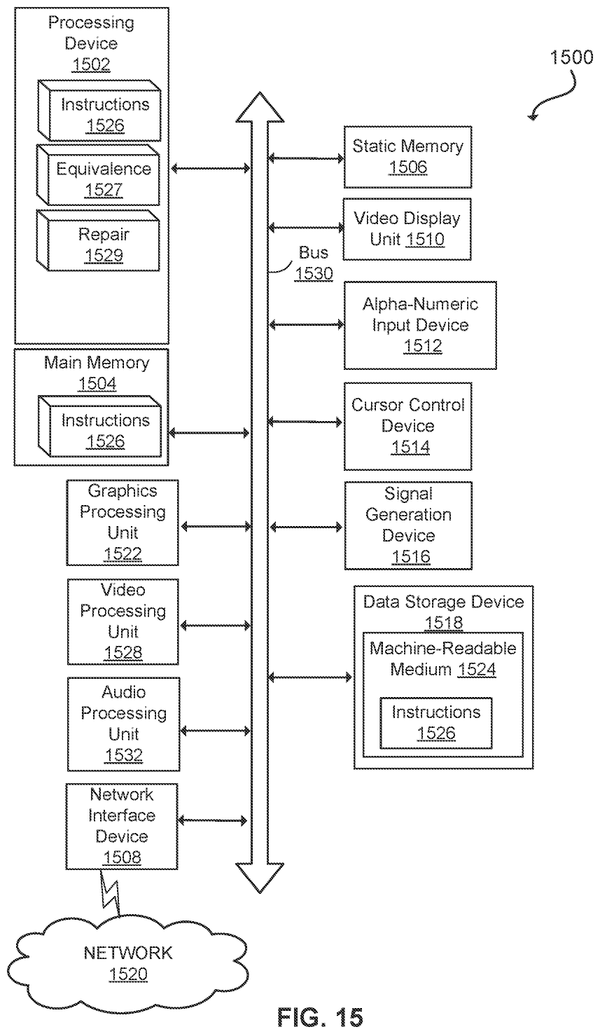

FIG. 6A is a flow diagram illustrating example operations 600 for establishing and/or creating subsystem equivalence, in accordance with certain aspects of the present disclosure. The operations 600 may be performed by processing device, which may include an equivalence system (e.g., equivalence system 1527 of FIG. 15), and in some aspects, a repair system (e.g., repair system 1529 of FIG. 15).

At 602, the equivalence system loads a circuit design (e.g., top-level design) to identify subsystem candidates for equivalence analysis. Buckets of subsystem instances that are candidates for equivalence analysis may be generated. In other words, each bucket may include similar subsystems (e.g., subsystems having logic size and/or area within a threshold). In some cases, area may refer to the number of FPGAs that would be used to implement the subsystem. In some cases, the number of FPGAs may be indicated by the user, or may be identified by the equivalence system based on the subsystem design. The content may include the type of logic contained in the subsystem. Instances in different buckets may be sufficiently different from each other that those are not candidates for equivalence match.

FIG. 6B illustrates the assignment of subsystems to various buckets for the circuit design 500, in accordance with certain aspects of the present disclosure. As shown, subsystems A and B may be similar in size and assigned to bucket 1. Subsystems J and C may be assigned to bucket 2. Subsystems D1 to D4, E1 to E4, F1 to F4, G1 to G4, and H1 to H4 may be assigned to bucket 3.

At 604 of FIG. 6A, for each subsystem bucket, the system performs an equivalence check using SS_EQ_CHECK_GI and/or SS_EQ_CHECK_LE. The system may generate subsystem instances grouped into sub-buckets where each sub-bucket contains equivalent subsystems that satisfy subsystem replication specifications.

FIG. 6C illustrates multiple sub-buckets 650 (e.g., of bucket 3 shown in FIG. 6B), in accordance with certain aspects of the present disclosure. For example, using SS_EQ_CHECK_GI and/or SS_EQ_CHECK_LE, subsystems D1 to D4 may be considered to be equivalent and assigned to a sub-bucket 612, subsystems E1 to E4 may be considered to be equivalent and assigned to a sub-bucket 614, subsystems F1 to F4 may be considered to be equivalent and assigned to a sub-bucket 616, subsystems G1 to G4 may be considered to be equivalent and assigned to a sub-bucket 618, and subsystems H1 to H4 may be considered to be equivalent and assigned to a sub-bucket 620, as shown.

At 606, the repair system analyzes whether two subsystems can be made equivalent by one or more design repair techniques. For example, the repair system may select one representative instance from each sub-bucket created at block 604. As shown in FIG. 6C, a subsystem may be selected from each of the sub-buckets 612, 614, 616, 618, 620, and considered for design repair.

A design repair phase's result may include some subsystems represented by repaired subsystem instances that replace the original subsystem instance. For example, subsystems D1 to D4 and E1 to E4, after design repair, may be replaced with replicated subsystems DE1 to DE8 (e.g., repaired subsystems), as shown. After design repair, subsystems F1 to F4, G1 to G4, and H1 to H4 may be replaced with replicated subsystems FGH1 to FGH8, as shown. Each repaired instance may have additional configuration signals that can configure the repaired instance to work as the original subsystem instance it replaces, as described in more detail herein. Configuring a subsystem's list and logic value may differ across different instances.

At 608, the processing device prepares the circuit design (e.g., a top-level design) for modular flow top-level partition. At this phase, the processing device uses a mix of original subsystem instances where no design repair was applied (e.g., subsystems J and C as shown in FIG. 5), and repaired subsystem instances where design repair was applied. In addition to original top-level inter-subsystem connectivity, additional replication information may be stored. Such information may include subsystem instances that are part of the same replication family, and hence, any partition or routing decisions are to be applied identically (or similarly) to each member of such family. The information may also include object correspondence such that if, for example, a certain partition or route operation is applied on one copy, it can be applied on a matching object in all copies.

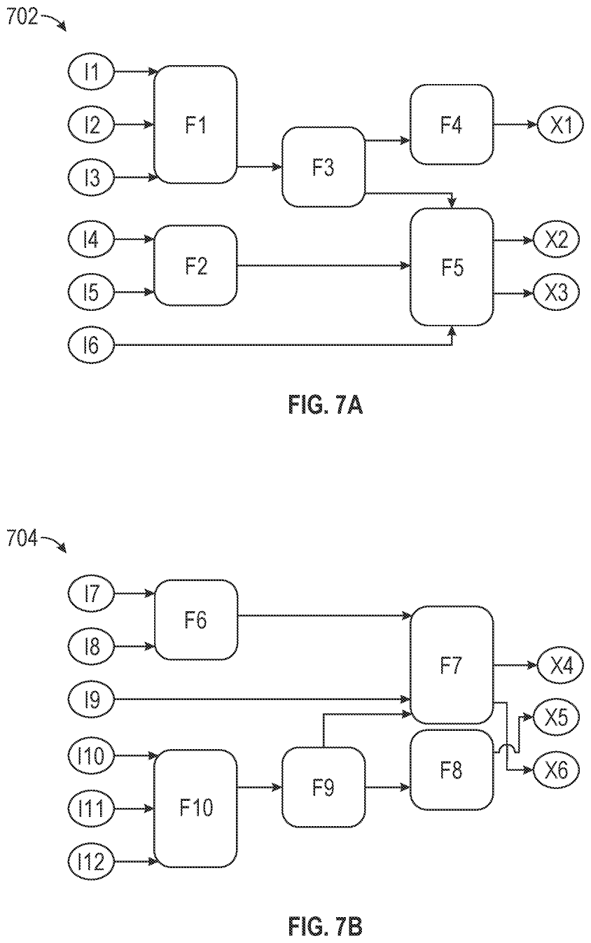

FIGS. 7A and 7B illustrate graph 702 and graph 704, respectively, used to perform a subsystem equivalence check using graph-isomorphism, in accordance with certain aspects of the present disclosure. As described, two sets of methods may be used to check for subsystem equivalence. The first set leverages graph-isomorphism techniques (e.g., SS_EQ_CHECK_GI) and applies additional graph node attributes and graph edge attributes to make the technique more widely applicable. The goal for the SS_EQ_CHECK_GI is to establish whether two subsystem descriptions as described by their graph structure are the same (isomorphic), and if so, establish a one-to-one correspondence between their respective graph nodes and graph edges. As shown, graph nodes are represented by nodes F1 to F5 in a first graph 702 and F6 to F10 in a second graph 704, each node representing a design circuit instance. Similarly, nodes I1 to I6 in the first graph 702 and I7 to I12 in the second graph 704 represent input port nodes, and nodes X1 to X3 in the first graph 702 and nodes X4 to X6 in the second graph 704 represent output ports for the respective subsystem. Graph edges model connectivity between two nodes may be identified, and may represent either scalar (one-bit) or vector (multi-bit) connectivity.

In some aspects, before applying SS_EQ_CHECK_GI, the graph representation may be enhanced for certain attributes that impact subsystem equivalence determination, including enhancing graph node functional attribute and graph edge order attribute.

The graph node functional attribute identifies the functionality being implemented by the circuit underlying each node. The graph node functionality may be considered a match if the respective graph node is bound to the same underlying circuit view (e.g., circuit description), and thus, implements the same functionality. For example, a graph node (e.g., circuit instance) may be selected from a hierarchy of circuits (e.g., including adders of various types) and, thus, may be associated with a description (e.g., of one of the adders in the hierarchy). In FIG. 7, nodes F1, F5, F6 and F10 are bound to the same circuit view. The graph node functionality may be considered a match if the respective graph nodes are bound to different underlying circuit views, but those views are proven to be equivalent based on SS_EQ_CHECK_LE techniques. The graph node functionality may be considered a match if respective graph nodes are bound to different underlying circuit views and are not found equivalent by logic-equivalence techniques, but SS_EQ_REPAIR is successfully applied (e.g., providing a match after repair with either SS_EQ_CHECK_GI or SS_EQ_CHECK_LE).

Graph edge order attribute identifies the order in which edges are considered incident on a node. For two graphs to match, this order match depends on whether the edge order is mutable or non-mutable. For example, edges incident on an AND circuit node (e.g., AND gate) can be incident in any order and hence, considered mutable, while edges incident on a division circuit node should be incident in a specific order and marked as non-mutable. In other words, reordering inputs to an AND gate will not change the output of the AND gate, and thus, the inputs to the AND gate are considered mutable. On the other hand, changing the order of inputs to a division circuit (e.g., flipping the numerator and denominator) will change the output of the divisional circuit, and thus, the inputs to a division circuit are non-mutable. In another case, a set of edges are individually non-mutable, but are mutable as a set with another set, such as the first operand of an adder circuit, with its second operand. For example, an adder may be adding two 8-bit values. Thus, the two 8-bit values may be swapped, but individual bits may not be swapped.

After annotating the graph node function attribute and graph edge order attribute on the respective objects of both graphs, the graph-isomorphism method is applied to determine the equivalence between the two graphs. If equivalence is established, the graph-isomorphism method returns one-to-one correspondence between nodes of respective graphs and between corresponding edges. For example, node F1 may be equivalent to node F10 (e.g., due to having the same view), node F5 may be equivalent to node F7 (e.g., different view, but with match by SS_EQ_CHECK_LE, and mutable edge order), and F3, F4, F8, and F9 may be equivalent with the same view name (e.g., edge order may not be relevant in some cases, such as where there is only one edge).

In some aspects, graph nodes may be created to represent both the internal design circuit as well as input and output ports on the boundary of the subsystem being compared. Hence, a successful match provides one-to-one correspondence on both the internal circuit nodes as well as boundary nodes. Because of mutability of edge order, it is possible that more than one successful match exists. In such cases, these methods leverage non-electrical meta-data such as instance names and port names to generate consistent and predictable match results. The techniques described herein may initially model a multi-bit connection as a single graph edge, keeping graph size smaller and helping to determine graph equivalence with lower compute effort. However, when such equivalence check fails, this method is executed again by replacing graph edges with a bit-expanded representation. In such representation, each bit of a multi-bit connection is represented by a separate edge.

Subsystem equivalence based on logic equivalence (SS_EQ_CHECK_LE) may be performed as a supplementary technique to SS_EQ_CHECK_GI. This may be to reduce compute efficiency because the parts of the design that are already established as equivalent based on methods SS_EQ_CHECK_GI may not be analyzed again by SS_EQ_CHECK_LE.

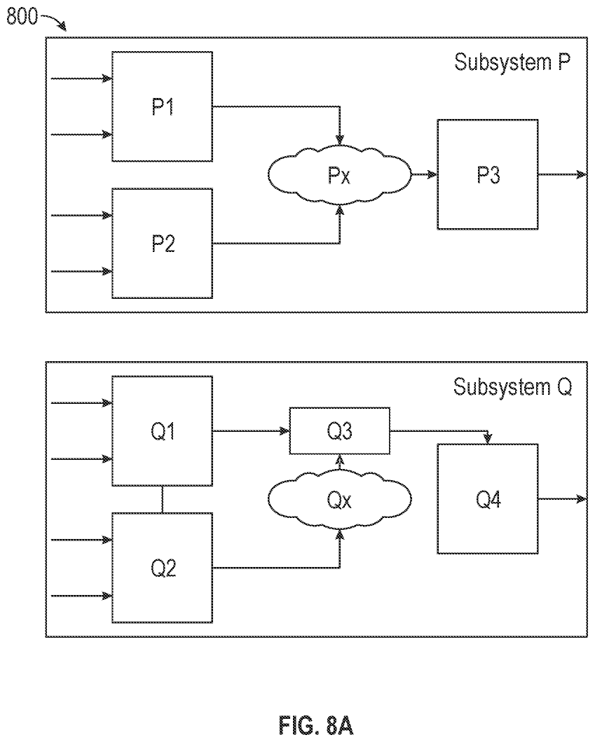

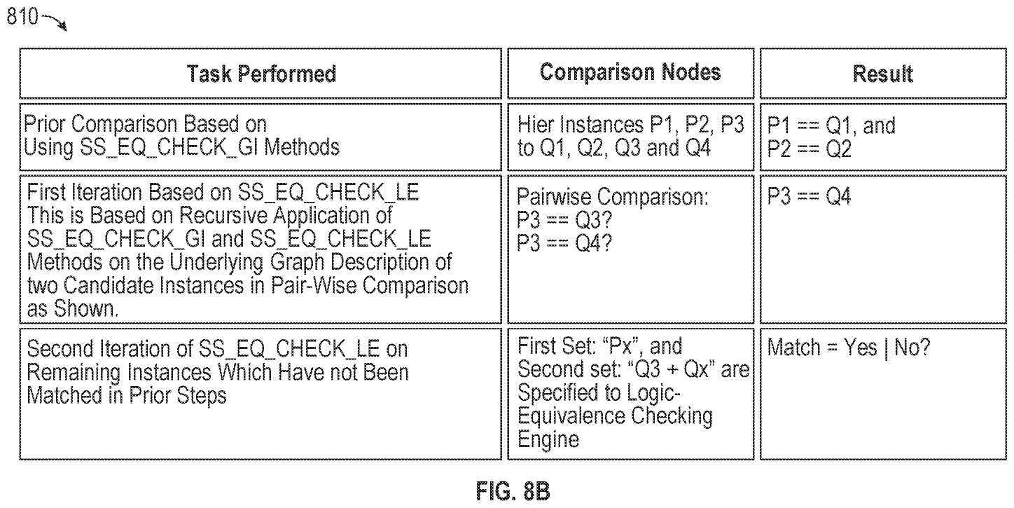

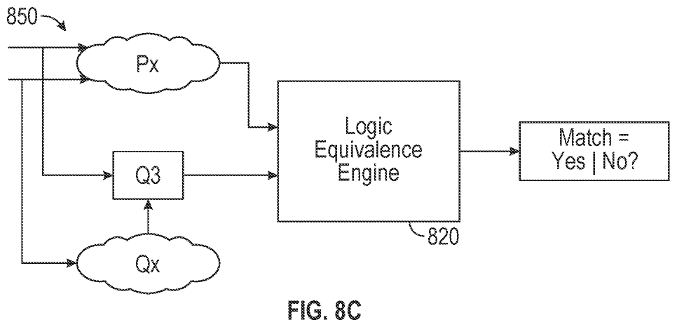

FIG. 8A illustrates a circuit design 800 having subsystems P and Q that are partially matched by SS_EQ_CHECK_GI. FIG. 8B is a table 810 describing equivalence tasks and results performed for subsystems P and Q, in accordance with certain aspects of the present disclosure.

Subsystem P may have hierarchical circuit instances P1, P2, and P3; the remaining circuit instance is collectively referred to as instance Px. In other words, circuit instances P1, P2, P3 may be selected from preconfigured circuit instances (e.g., hierarchical instances), such as preconfigured adder types. On the other hand, circuit instance Px may not be selected from a preconfigured list of circuit instances (e.g., created separately using individual logic gates). Similarly, subsystem Q has hierarchical instances Q1, Q2, Q3 and Q4, and the remaining circuit instance is collectively referred to as instance Qx. As an example, assume SS_EQ_CHECK_GI has established that hierarchical instance P1 matches with hierarchical instance Q1 and hierarchical instance P2 matches with hierarchical instance Q2, and the remaining hierarchical and/or non-hierarchical instances are not matched, as shown in FIG. 8B.

After SS_EQ_CHECK_GI has identified that circuit instance P1 is equivalent to circuit instance P2, and circuit instance Q1 is equivalent to circuit instance Q2, SS_EQ_CHECK_LE may be performed with two iterations. In a first iteration of SS_EQ_CHECK_LE, hierarchical instances may be matched only to other hierarchical instances, and non-hierarchical instances may be matched with non-hierarchical instances. This is possible when there are the same number of unmatched hierarchical instances in both cases. The techniques for matching hierarchical instances are described in more detail herein. In a second iteration, scenarios where logic described as a hierarchical instance in one case and described as a non-hierarchical circuit in a second case, and vice-versa, are analyzed, as described in more detail herein. The results of equivalence techniques are that equivalent subsystems or parts thereof are identified for both scenarios where the description is represented by the same graph-structure, or where the graph structure is different but the underlying functionality identified by logic-equivalence is the same. The compute effort for SS_EQ_CHECK_LE may be higher than SS_EQ_CHECK_GI, and hence, a mix of both techniques may be used to increase compute efficiency.

As described, hierarchical instances may be compared for logic equivalence. As illustrated in FIG. 8A, this can cover a subset of hierarchical instances which can be matched to each other. During the first iteration of SS_EQ_CHECK_LE, hierarchical instances may be matched by recursive application of SS_EQ_CHECK_GI and SS_EQ_CHECK LE. For instance, the equivalence system may identify whether circuit instance P3 is equivalent to circuit instance Q3 or circuit instance Q4, as shown in FIG. 8B. Using SS_EQ_CHECK_GI, hierarchical instances having the same view name (underlying circuit description), or different view name but previously established to be equivalent with same or different port interface order may be matched. Then, hierarchical instances not matched by SS_EQ_CHECK_GI may be further compared in a pair-wise manner using SS_EQ_CHECK_LE. The system may establish the equivalence of, for example, subsystems P3 and Q3 (e.g., hierarchical instances) in the same manner that the equivalence of subsystems P and Q may be established as described herein. As shown, the equivalence system may identify that circuit instance P3 is equivalent to circuit instance Q4. Then, as shown in FIG. 8B, circuit instance Px from subsystem P and collectively circuit instances Q3 and Qx from subsystem Q may be further compared using a logic equivalence check engine, as described in more detail with respect to FIG. 8C.

FIG. 8C illustrates unmatched logic 850 represented as two clusters, in accordance with certain aspects of the present disclosure. The cluster of unmatched logic from subsystem P is, as an example, collection of only non-hierarchical instances collectively referred to as Px. Cluster of unmatched logic from subsystem Q is, as an example, collection of both unmatched hierarchical instance Q3 and non-hierarchical instances collectively referred to as Qx. In this case, the logic in one or more hierarchical instances is flattened to the same level as the cluster being compared, such that the system has full view of the complete circuit. The two cluster description is given as input to the logic equivalence check engine 820. In some aspects, the logic equivalence check engine 820 may be implemented by a circuit or processor such as the processing device 1502. From equivalence of an already matched circuit, the system may establish non-variant inputs and outputs to assist the logic equivalence check engine 820 to perform an equivalence task. The result of the logic equivalence check engine 820 is a determination of whether subsystems Px and Q3/Qx are equivalent or not. For example, logic equivalence check engine 820 may provide various inputs to subsystems Px and Q3/Qx, and check to see if the outputs of the subsystems are the same in response to the various inputs. If so, the subsystems may be identified as equivalents.

In cases where equivalence is not found, the logic equivalence check engine 820 may provide a report and counterexample of the cause of mismatch, allowing an end-user to debug and understand why two subsystems were not found equivalent. If subsystems are non-equivalent at this stage, an equivalence repair technique (referred to design repair or SS_EQ_REPAIR) may be performed.

As described herein with respect to FIG. 6C, subsystem equivalence candidates are grouped into different buckets, and each bucket is further sub-grouped into sub-buckets of equivalent subsystem instances. For design repair, the system may select one representative instance from each sub-bucket. For example, bucket 3 may have five sub-buckets. From each sub-bucket, one representative instance named D1, E1, F1, G1 and H1 respectively may be selected, and pair-wise design repair analysis is performed (e.g., D1 is compared with E1, then D1 is compared with F1, and so on). Bucket 2 may have two sub-buckets containing one instance each, which are evaluated for design repair within acceptable cost. Bucket 1 may have only 1 sub-bucket and hence, has no opportunity for further replication improvement.

Design repair analysis is described across two subsystem instances. When there are more than two candidates, the system performs pair-wise analysis and selects the result based on lowest cost of design repair across various pairs. For example, it may be possible to perform design repair to generate a replicated circuit for subsystems D1 and E1, and also D1 and F1. In this case, the replicated circuit DE1 and DF1 may be compared and the one with smaller size may be implemented. In other words, if the size of replicated circuit DE1 is less than DF1, then design repair may be implemented for subsystems D1 and E1.

Design repair may be described herein at a subsystem level to facilitate understanding. However, actual application may be recursive in nature. That is, the methods employed to create equivalence between two subsystem candidates may be also recursively used to create equivalence between two candidate instances within respective subsystem circuits.

Design repair techniques may be described in two phases. The first phase may involve creation of equivalence between nodes. The successful result of the first phase is that both subsystem will have equal number of nodes with matching functionality, though actual one-to-one correspondence may depend on the equivalence of edges incident on each node. The second phase includes seeking to establish equivalence of edges, which may involve reordering of mutable edges, as well as creation of redundant edges as long as original functionality is maintained.

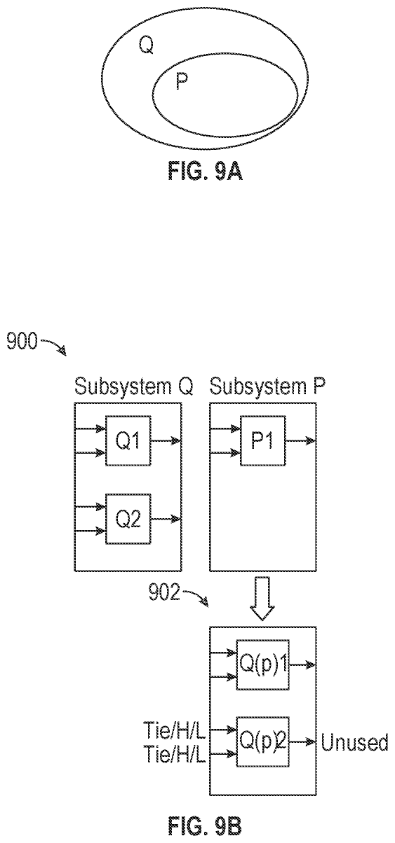

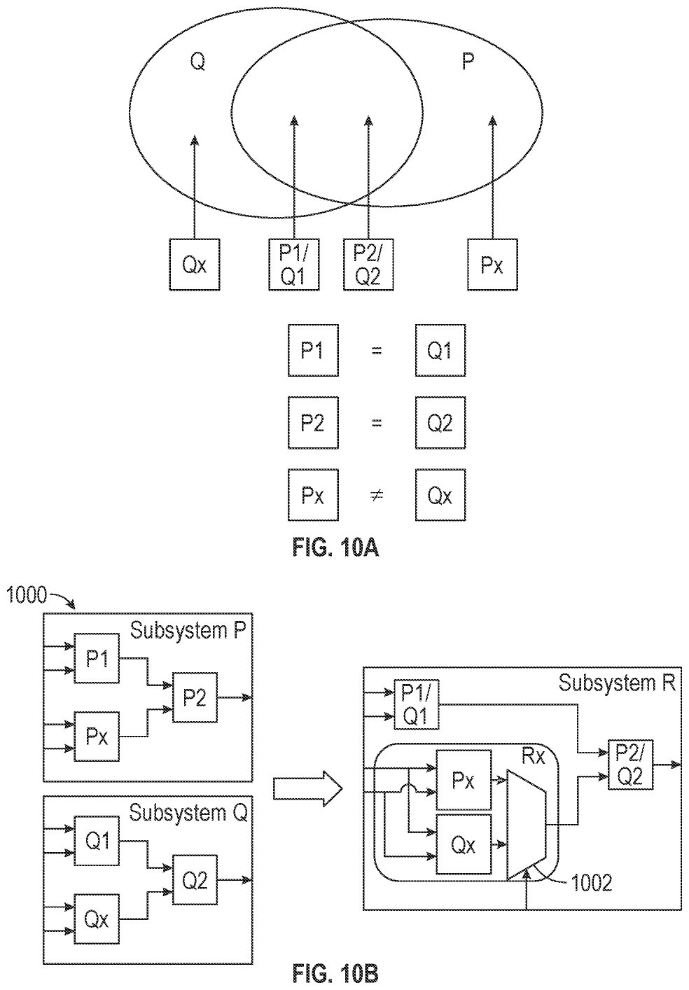

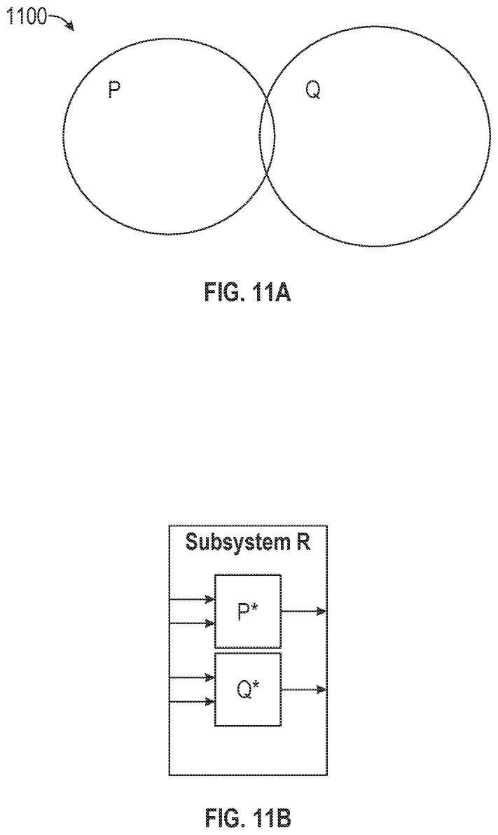

To facilitate understanding of the first phase, consider two subsystems P and Q. Graph isomorphism techniques may be enhanced to not just check for equivalence, but demarcate equivalent and non-equivalent sub-sets from the input graph of subsystems P and Q. Possible outcomes are described in more detail with respect to FIG. 9B, FIG. 10B, and FIG. 11B.

FIGS. 9A and 9B illustrate an outcome of design repair where graph node P (e.g., subsystem P) is a proper subset of graph node Q (e.g., subsystem Q) in a circuit design 900, in accordance with certain aspects of the present disclosure. In other words, subsystem P is a proper subset of subsystem Q if all functionality of subsystem P can be realized by using subsystem Q. For instance, subsystem P is a proper subset of subsystem Q if subsystem Q includes circuitry for multiply and accumulate and subsystem P includes circuitry for only multiplication. Thus, all of the functionality of subsystem P can be performed by subsystem Q. In this case, the design repair may involve replacing subsystem P with subsystem Q for all instances of P, as shown in FIG. 9B. In other words, the replicated subsystem 902 replaces subsystem P and subsystem Q, and the replicated subsystem 902 is the same subsystem Q.

The design repair may be performed if the cost of the repair meets acceptance criteria (e.g., the size increase for subsystem P when replaced with replicated subsystem 902 is less than a threshold). Suppose the repair is applied at a lower-level design hierarchy node (e.g., being recursive in nature). In that case, acceptance criteria may be defined as the acceptable percentage increase in the design area. If this repair is performed at a subsystem level, then repair may be acceptable because subsystem Q has to be implemented irrespective of whether subsystem P applies this repair or not.

When analyzing the result from the comparison of subsystems P and Q, and subsystem P is a proper subset of subsystem Q, the repair system may create a representation of subsystem Q that will replace for subsystem P. The representation of subsystem Q may be referred to as subsystem Q(p) (e.g., replicated subsystem Q(p)). In subsystem Q(p), unmatched input nodes of subsystem Q may be provided a blocking logic value for the driven gate at the respective input node. For instance, as shown in FIG. 9B, assume subsystem Qp(1) of replicated subsystem 902 is a multiplier circuit and subsystem Qp(2) is an accumulator circuit. When the replicated subsystem 902 replaces subsystem P (e.g., only having the function of multiplication), subsystem Qp(2) may be unused. Thus, the inputs for subsystem Qp(2) may be provided blocking logic values. For instance, if an input of subsystem Qp(2) feeds an input of an AND gate, then the blocking logic value may be logic low (e.g., since the output of the AND gate will be logic low if any of the AND gate's inputs is logic low). Inputs where the logic value is indeterminate may be provided a logic low. In other words, to realize subsystem P from subsystem Q(p), the extra instance Q(p)2 is inactivated by tying input ports of Q2 to appropriate logic values and ignoring unused outputs of Q(p)2. All instances of subsystem P may now be bound to subsystem Q(p) for the purpose of modular flow implementation. The sub-bucket of subsystem P may be removed for further analysis. Subsystem Q is retained for other cases of pair-wise subsystem analysis.

FIGS. 10A and 10B illustrate an outcome of design repair where the functionality of subsystem P partially overlaps with the functionality of subsystem Q in a circuit design 1000, in accordance with certain aspects of the present disclosure. For instance, subsystem Q may have circuit instances Q1, Q2 that are equivalent to circuit instances P1, P2 of subsystem P, respectively. Instances in subsystem P that do not have counterparts in subsystem Q are represented as instance Px. Similarly, instances in subsystem Q which do not have counterparts in subsystem P are represented as instance Qx. For the sake of simplicity, the subsystem input and output port nodes are not illustrated in FIG. 10A. As shown in FIG. 10B, unmatched logic as represented by instances Px and Qx may be combined by a multiplexing structure to form a superset circuit instance Rx, as shown.

After analyzing subsystems P and Q, the nodes of the subsystems are separated in two categories, including matched nodes as represented by circuit instances P1/Q1 and P2/Q2, and unmatched nodes, collectively referred to as circuit instances Px and Qx. The design repair method aims to create graph R (e.g., a replicated subsystem R), which may be the lowest cost superset of graphs P and Q (e.g., subsystems P and Q). Two sub-steps may be followed to create subsystem R, including copying matched nodes and edges as represented by subsystems P1/Q1 and P2/Q2, and creating a circuit instance Rx including a multiplexing structure. For instance, circuit instance Rx may include a high-level multiplexer 1002, which receives the output of circuit instance Px as a first data input and the output of circuit instance Qx as a second data input. A control signal may be provided to the multiplexer 1002 to select circuit instance Px when the replicated subsystem replaces subsystem P and select circuit instance Qx when the replicated subsystem replaces subsystem Q.

The control signal for the multiplexer may be provided from a boundary of subsystem R and may be controlled externally to make subsystem R behave as either subsystem P or subsystem Q. In some aspects, the control signal for the multiplexer may be configured using FPGA firmware without external port control. In other words, the FPGA used to implement the multiplexer may include firmware configured to provide the appropriate control signal to the multiplexer.

The circuit instance Rx may be improved using any suitable logic-improvement engine. The goal of the logic improvement engine may be to merge redundant logic between circuit instances Px and Qx and hence, reduce the overall size of new circuit instance Rx. After improving the logic for the circuit instances, incremental cost (R_{incremental_cost}) of the subsystem R may be computed as:

$${R}_{incremental \_ cost} = Max ( \frac{Size ( Rx )}{Size ( Px )} , \frac{Size ( Rx )}{Size ( Qx )} ) - 1$$

or in some cases:

$${R}_{incremental \_ cost} = Max ( Size ( Rx ) - Size ( Px ) , Size ( Rx ) - Size ( Qx ) )$$

where Size(Rx) is the size of circuit instance Rx, Size(Px) is the size of circuit instance Px, Size(Qx) is the size of circuit instance Qx. Suppose the cost is within an acceptance threshold as specified by user, or heuristically determined by software application. In that case, design repair may be used (e.g., replicated subsystem R may be used to replace subsystems P and Q). All instances of subsystem P may now be bound to subsystem R for modular flow implementation, and the multiplexer select signal (e.g., control signal) is set to a value that enables Px logic. Similarly, all instances of subsystem Q are now bound to subsystem R for the purpose of modular flow implementation, and the multiplexer select signal is set to a value that enables Qx logic. In some aspects, the multiplexer control signal is configured by FPGA firmware without external port control. The sub-bucket of subsystem P and subsystem Q may be removed for further analysis. Subsystem R may be added for other cases of pair-wise subsystem analysis.

FIGS. 11A and 11B illustrate subsystems 1100 with little to no overlap (e.g., function overlap between subsystems 1100 (e.g., subsystems P and Q) is less than a threshold). In this case, subsystems P and Q may be marked as incompatible candidates for design repair, as the repair may prevent a full copy of subsystems P and Q from being implemented in the merged subsystem R, and overhead may be too high to implement this merged system R in the same number of FPGAs. However, as illustrated in FIG. 11B, there may be cases where subsystem P and subsystem Q are small enough such that even with merging the subsystems into a new subsystem R, an implementation of subsystem R can be realized with the same number of FPGAs as subsystem P or subsystem Q. This design repair technique may be applied if the computed cost of the new subsystem R is within an acceptance threshold as specified by the user, or heuristically determined by a software application. As described, the sub-bucket of subsystem P and subsystem Q may be removed for further analysis. Subsystem R may be added for other cases of pair-wise subsystem analysis.

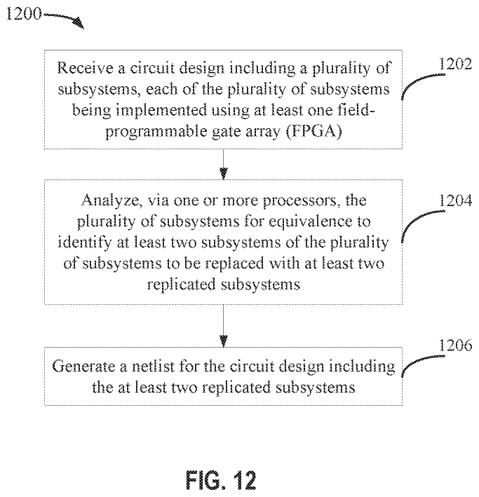

FIG. 12 is a flow diagram illustrating example operations 1200 for circuit equivalence processing in accordance with certain aspects of the present disclosure. The operations 1200 may be performed by a processing device, which may include an equivalence system (e.g., equivalent system 1527 of FIG. 15) and in some aspects, a repair system (e.g., repair system 1529 of FIG. 15).

At 1202, the processing device receives a circuit design including a plurality of subsystems, each of the plurality of subsystems being implemented using at least one field-programmable gate array (FPGA).

At 1204, the processing device analyzes the plurality of subsystems for equivalence to identify at least two subsystems of the plurality of subsystems to be replaced with at least two replicated subsystems. At 1206, the processing device generates a netlist for the circuit design including the at least two replicated subsystems.

In some aspects, the at least two subsystems may have different circuit structures and may be identified to be equivalent based on logic of the at least two subsystems serving a same logic function. In some aspects, the at least two subsystems include at least a first subsystem (e.g., subsystem P) and a second subsystem (e.g., subsystem Q), at least one first circuit instance (e.g., circuit instance Px of FIG. 8C) of the first subsystem being different than at least one second circuit instance (e.g., circuit instances Q3 and Qx of FIG. 8C) of the second subsystem. To identify the at least two subsystems, the processing device may identify (e.g., via the logic equivalence check engine 820 of FIG. 8C) whether the at least one first circuit instance and the at least one second circuit instance generate the same one or more outputs in response to one or more inputs.

In some aspects, the analyzing of the plurality of subsystems for equivalence may be performed using graph-isomorphism. The at least two subsystems may be identified to be equivalent based on a circuit description associated with the at least two subsystems being the same. The at least two subsystems may be identified to be equivalent by analyzing one or more inputs and one or more outputs of each subsystem of the at least two subsystems. The one or more inputs may include multiple inputs, and analyzing the multiple inputs may include identifying whether the multiple inputs are mutable. For example, identifying whether the one or more inputs are mutable may include identifying whether an order of the multiple inputs can be changed without changing a function of the subsystem.

In some cases, the at least two subsystems includes at least a first subsystem (e.g., subsystem P) and a second subsystem (e.g., subsystem Q), the at least two subsystems being identified based on whether an entirety of the first subsystem is equivalent to a subset of the second subsystem (e.g., whether the subsystem P is a proper subset of subsystem Q, as described with respect to FIGS. 9A and 9B). For example, each of the at least two replicated subsystems may replicate the second subsystem based on the entirety of the first subsystem being equivalent to the subset of the second subsystem. In some aspects, the at least two replicated subsystems may include a first replicated subsystem to replace the first subsystem and a second replicated subsystem to replace the second subsystem. A circuit instance (e.g., instance Q(p)2 shown in FIG. 9B) of the first replicated subsystem is deactivated.

In some aspects, the at least two subsystems include at least a first subsystem (e.g., subsystem P) and a second subsystem (subsystem Q), a first circuit instance (e.g., circuit instance Px) of the first subsystem being different than a second circuit instance (e.g., circuit instance Qx) of the second subsystem. Each of the at least two replicated subsystems may include a multiplexer (e.g., multiplexer 1002 of FIG. 10B) having a first input coupled to the first circuit instance and a second input coupled to the second circuit instance. The at least two replicated subsystems may include a first replicated subsystem to replace the first subsystem and a second replicated subsystem to replace the second subsystem. The multiplexer of the first replicated subsystem may be configured to receive a first control signal to select the first circuit instance of the first subsystem and the multiplexer of the second replicated subsystem may be configured to receive a second control signal to select the second circuit instance of the second subsystem.

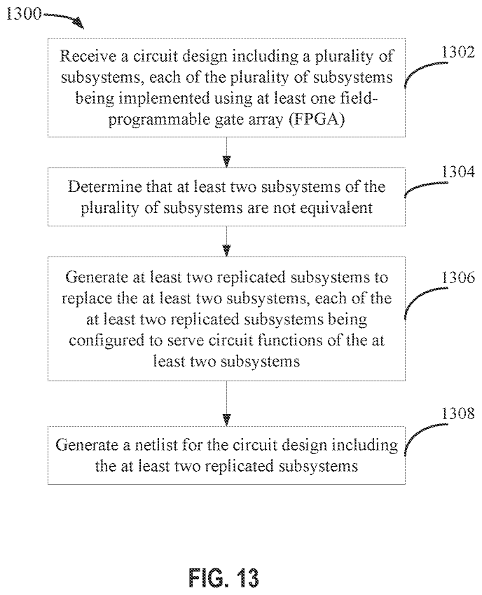

FIG. 13 is a flow diagram illustrating example operations 1300 for circuit equivalence processing in accordance with certain aspects of the present disclosure. The operations 1300 may be performed by a processing device, which may include an equivalence system (e.g., equivalent system 1527 of FIG. 15) and in some aspects, a repair system (e.g., repair system 1529 of FIG. 15).

At 1302, the processing device receives a circuit design including a plurality of subsystems, each of the plurality of subsystems being implemented using at least one FPGA. At 1304, the processing device determines that at least two subsystems of the plurality of subsystems are not equivalent.

At 1306, the processing device generates at least two replicated subsystems (e.g., subsystems P and Q) to replace the at least two subsystems. Each of the at least two replicated subsystems may be configured to serve circuit functions of the at least two subsystems. At 1308, the processing device generates a netlist for the circuit design including the at least two replicated subsystems.

In some aspects, the at least two subsystems include at least a first subsystem (e.g., subsystem P) and a second subsystem (e.g., subsystem Q) and an entirety of the first subsystem is equivalent to a subset of the second subsystem (e.g., subsystem P is a proper subset of subsystem Q). In this case, each of the at least two replicated subsystems may be generated to replicate the second subsystem based on the entirety of the first subsystem being equivalent to the subset of the second subsystem. The at least two replicated subsystems may include a first replicated subsystem to replace the first subsystem and a second replicated subsystem to replace the second subsystem, and a circuit instance (e.g., circuit instance Q(p)2 of FIG. 19B) of the first replicated subsystem may be deactivated.

In some aspects, the at least two subsystems include at least a first subsystem (e.g., subsystem P) and a second subsystem (e.g., subsystem Q), a first circuit instance (e.g., instance Px) of the first subsystem being different than a second circuit instance (e.g., instance Qx) of the second subsystem. Each of the at least two replicated subsystems may include a multiplexer (e.g., multiplexer 1002 of FIG. 10B) having a first input coupled to the first circuit instance and a second input coupled to the second circuit instance. The at least two replicated subsystems may include a first replicated subsystem to replace the first subsystem and a second replicated subsystem to replace the second subsystem. The multiplexer of the first replicated subsystem may be configured to receive a first control signal to select the first circuit instance of the first subsystem and the multiplexer of the second replicated subsystem may be configured to receive a second control signal to select the second circuit instance of the second subsystem.

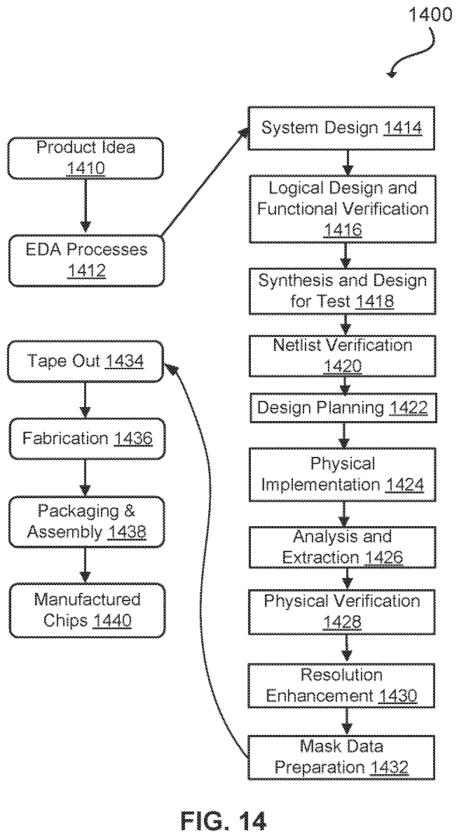

FIG. 14 illustrates an example set of processes 1400 used during the design, verification, and fabrication of an article of manufacture such as an integrated circuit to transform and verify design data and instructions that represent the integrated circuit. Each of these processes can be structured and enabled as multiple modules or operations. The term ‘EDA’ signifies the term ‘Electronic Design Automation.’ These processes start with the creation of a product idea 1410 with information supplied by a designer, information which is transformed to create an article of manufacture that uses a set of EDA processes 1412. When the design is finalized, the design is taped-out 1434, which is when artwork (e.g., geometric patterns) for the integrated circuit is sent to a fabrication facility to manufacture the mask set, which is then used to manufacture the integrated circuit. After tape-out, a semiconductor die is fabricated 1436 and packaging and assembly processes 1438 are performed to produce the finished integrated circuit 1440.

Specifications for a circuit or electronic structure may range from low-level transistor material layouts to high-level description languages. A high-level representation may be used to design circuits and systems, using a hardware description language (‘HDL’) such as VHDL, Verilog, System Verilog, SystemC, MyHDL or OpenVera. The HDL description can be transformed to a logic-level register transfer level (‘RTL’) description, a gate-level description, a layout-level description, or a mask-level description. Each lower representation level that is a more detailed description adds more useful detail into the design description, for example, more details for the modules that include the description. The lower levels of representation that are more detailed descriptions can be generated by a computer, derived from a design library, or created by another design automation process. An example of a specification language at a lower level of representation language for specifying more detailed descriptions is SPICE, which is used for detailed descriptions of circuits with many analog components. Descriptions at each level of representation are enabled for use by the corresponding tools of that layer (e.g., a formal verification tool). A design process may use a sequence depicted in FIG. 14. The processes described by be enabled by EDA products (or tools).

During system design 1414, functionality of an integrated circuit to be manufactured is specified. The design may be optimized for desired characteristics such as power consumption, performance, area (physical and/or lines of code), and reduction of costs, etc. Partitioning of the design into different types of modules or components can occur at this stage.

During logic design and functional verification 1416, modules or components in the circuit are specified in one or more description languages and the specification is checked for functional accuracy. For example, the components of the circuit may be verified to generate outputs that match the requirements of the specification of the circuit or system being designed. Functional verification may use simulators and other programs such as testbench generators, static HDL checkers, and formal verifiers. In some embodiments, special systems of components referred to as ‘emulators’ or ‘prototyping systems’ are used to speed up the functional verification.

During synthesis and design for test 1418, HDL code is transformed to a netlist. In some embodiments, a netlist may be a graph structure where edges of the graph structure represent components of a circuit and where the nodes of the graph structure represent how the components are interconnected. Both the HDL code and the netlist are hierarchical articles of manufacture that can be used by an EDA product to verify that the integrated circuit, when manufactured, performs according to the specified design. The netlist can be optimized for a target semiconductor manufacturing technology. Additionally, the finished integrated circuit may be tested to verify that the integrated circuit satisfies the requirements of the specification.

During netlist verification 1420, the netlist is checked for compliance with timing constraints and for correspondence with the HDL code. During design planning 1422, an overall floor plan for the integrated circuit is constructed and analyzed for timing and top-level routing.

During layout or physical implementation 1424, physical placement (positioning of circuit components such as transistors or capacitors) and routing (connection of the circuit components by multiple conductors) occurs, and the selection of cells from a library to enable specific logic functions can be performed. As used herein, the term ‘cell’ may specify a set of transistors, other components, and interconnections that provides a Boolean logic function (e.g., AND, OR, NOT, XOR) or a storage function (such as a flipflop or latch). As used herein, a circuit ‘block’ may refer to two or more cells. Both a cell and a circuit block can be referred to as a module or component and are enabled as both physical structures and in simulations. Parameters are specified for selected cells (based on ‘standard cells’) such as size and made accessible in a database for use by EDA products.

During analysis and extraction 1426, the circuit function is verified at the layout level, which permits refinement of the layout design. During physical verification 1428, the layout design is checked to ensure that manufacturing constraints are correct, such as DRC constraints, electrical constraints, lithographic constraints, and that circuitry function matches the HDL design specification. During resolution enhancement 1430, the geometry of the layout is transformed to improve how the circuit design is manufactured.

During tape-out, data is created to be used (after lithographic enhancements are applied if appropriate) for production of lithography masks. During mask data preparation 1432, the ‘tape-out’ data is used to produce lithography masks that are used to produce finished integrated circuits.

A storage subsystem of a computer system (such as computer system 1500 of FIG. 15) may be used to store the programs and data structures that are used by some or all of the EDA products described herein, and products used for development of cells for the library and for physical and logical design that use the library.

FIG. 15 illustrates an example machine of a computer system 1500 within which a set of instructions, for causing the machine to perform any one or more of the methodologies discussed herein, may be executed. In alternative implementations, the machine may be connected (e.g., networked) to other machines in a LAN, an intranet, an extranet, and/or the Internet. The machine may operate in the capacity of a server or a client machine in client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 1500 includes a processing device 1502, a main memory 1504 (e.g., read-only memory (ROM), flash memory, dynamic random access memory (DRAM) such as synchronous DRAM (SDRAM), a static memory 1506 (e.g., flash memory, static random access memory (SRAM), etc.), and a data storage device 1518, which communicate with each other via a bus 1530.

Processing device 1502 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 1502 may also be one or more special-purpose processing devices such as an application specific integrated circuit (ASIC), a field programmable gate array (FPGA), a digital signal processor (DSP), network processor, or the like. The processing device 1502 may be configured to execute instructions 1526 for performing the operations and steps described herein.

The computer system 1500 may further include a network interface device 1508 to communicate over the network 1520. The computer system 1500 also may include a video display unit 1510 (e.g., a liquid crystal display (LCD) or a cathode ray tube (CRT)), an alphanumeric input device 1512 (e.g., a keyboard), a cursor control device 1514 (e.g., a mouse), a graphics processing unit 1522, a signal generation device 1516 (e.g., a speaker), graphics processing unit 1522, video processing unit 1528, and audio processing unit 1532.

The data storage device 1518 may include a machine-readable storage medium 1524 (also known as a non-transitory computer-readable medium) on which is stored one or more sets of instructions 1526 or software embodying any one or more of the methodologies or functions described herein. The instructions 1526 may also reside, completely or at least partially, within the main memory 1504 and/or within the processing device 1502 during execution thereof by the computer system 1500, the main memory 1504 and the processing device 1502 also constituting machine-readable storage media.

In some implementations, the instructions 1526 include instructions to implement functionality corresponding to the present disclosure. While the machine-readable storage medium 1524 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 1502 to perform any one or more of the methodologies of the present disclosure. The term “machine-readable storage medium” shall accordingly be taken to include, but not be limited to, solid-state memories, optical media, and magnetic media.

In some aspects of the present disclosure, the processing device 1502 may include an equivalence system 1527 (e.g., configured to identify equivalence of subsystems or circuit instances) and a repair system 1529 (e.g., circuit configured to perform design repair operations).

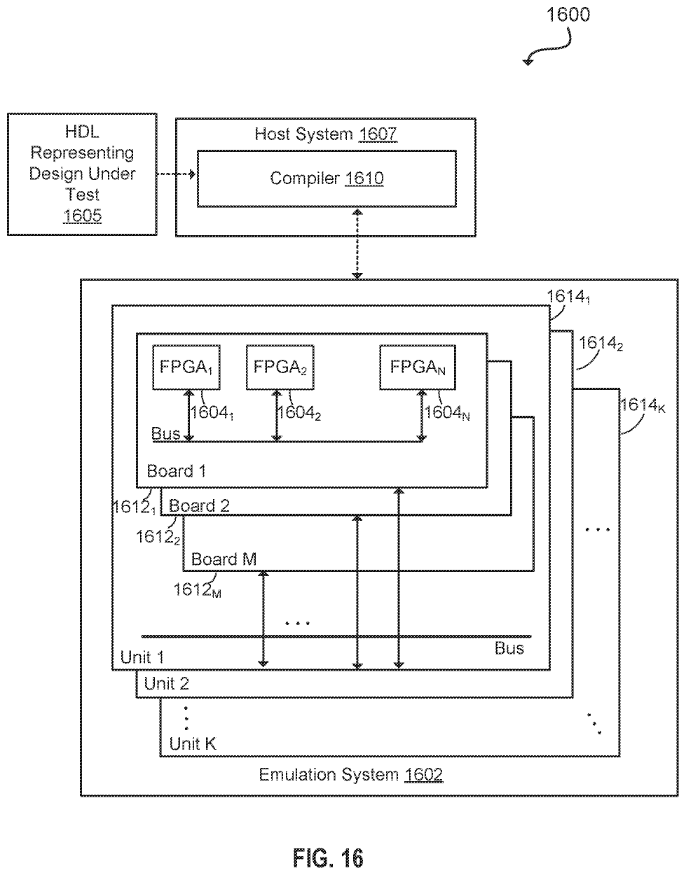

FIG. 16 depicts a diagram of an example emulation environment 1600. In some cases, the emulation environment 1600 may be used for prototyping a circuit design. An emulation environment 1600 may be configured to verify the functionality of the circuit design. The emulation environment 1600 may include a host system 1607 (e.g., a computer that is part of an EDA system) and an emulation system 1602 (e.g., a set of programmable devices such as Field Programmable Gate Arrays (FPGAs) or processors). The host system generates data and information by using a compiler 1610 to structure the emulation system to emulate a circuit design. A circuit design to be emulated is also referred to as a Design Under Test (‘DUT’) where data and information from the emulation are used to verify the functionality of the DUT.

The host system 1607 may include one or more processors. In the example where the host system includes multiple processors, the functions described herein as being performed by the host system can be distributed among the multiple processors. The host system 1607 may include a compiler 1610 to transform specifications written in a description language that represents a DUT and to produce data (e.g., binary data) and information that is used to structure the emulation system 1602 to emulate the DUT. The compiler 1610 can transform, change, restructure, add new functions to, and/or control the timing of the DUT.

The host system 1607 and emulation system 1602 exchange data and information using signals carried by an emulation connection. The connection can be, but is not limited to, one or more electrical cables such as cables with pin structures compatible with the Recommended Standard 232 (RS232) or universal serial bus (USB) protocols. The connection can be a wired communication medium or network such as a local area network or a wide area network such as the Internet. The connection can be a wireless communication medium or a network with one or more points of access using a wireless protocol such as BLUETOOTH or IEEE 802.11. The host system 1607 and emulation system 1602 can exchange data and information through a third device such as a network server.

The emulation system 1602 includes multiple FPGAs (or other modules) such as FPGAs 1604₁ and 1604₂ as well as additional FPGAs to 1604_{N}. Each FPGA can include one or more FPGA interfaces through which the FPGA is connected to other FPGAs (and potentially other emulation components) for the FPGAs to exchange signals. An FPGA interface can be referred to as an input/output pin or an FPGA pad. While an emulator may include FPGAs, examples of emulators can include other types of logic blocks instead of, or along with, the FPGAs for emulating DUTs. For example, the emulation system 1602 can include custom FPGAs, specialized ASICs for emulation or prototyping, memories, and input/output devices.

A programmable device can include an array of programmable logic blocks and a hierarchy of interconnections that can enable the programmable logic blocks to be interconnected according to the descriptions in the HDL code. Each of the programmable logic blocks can enable complex combinational functions or enable logic gates such as AND, and XOR logic blocks. In some examples, the logic blocks also can include memory elements/devices, which can be simple latches, flip-flops, or other blocks of memory. Depending on the length of the interconnections between different logic blocks, signals can arrive at input terminals of the logic blocks at different times and thus may be temporarily stored in the memory elements/devices.

FPGAs 1604₁-1604_{N} may be placed onto one or more boards 1612₁ and 1612₂ as well as additional boards through 1612_{M}. Multiple boards can be placed into an emulation unit 1614₁. The boards within an emulation unit can be connected using the backplane of the emulation unit or any other types of connections. In addition, multiple emulation units (e.g., 1614₁ and 1614₂ through 1614_{K}) can be connected to each other by cables or any other means to form a multi-emulation unit system.

For a DUT that is to be emulated, the host system 1607 transmits one or more bit files to the emulation system 1602. The bit files may specify a description of the DUT and may further specify partitions of the DUT created by the host system 1607 with trace and injection logic, mappings of the partitions to the FPGAs of the emulator, and design constraints. Using the bit files, the emulator structures the FPGAs to perform the functions of the DUT. In some examples, one or more FPGAs of the emulators may have the trace and injection logic built into the silicon of the FPGA. In such an example, the FPGAs may not be structured by the host system to emulate trace and injection logic.

The host system 1607 receives a description of a DUT that is to be emulated. In some examples, the DUT description is in a description language (e.g., a register transfer language (RTL)). In some examples, the DUT description is in netlist level files or a mix of netlist level files and HDL files. If part of the DUT description or the entire DUT description is in an HDL, then the host system can synthesize the DUT description to create a gate level netlist using the DUT description. A host system can use the netlist of the DUT to partition the DUT into multiple partitions where one or more of the partitions include trace and injection logic. The trace and injection logic traces interface signals that are exchanged via the interfaces of an FPGA. Additionally, the trace and injection logic can inject traced interface signals into the logic of the FPGA. The host system maps each partition to an FPGA of the emulator. In some examples, the trace and injection logic is included in select partitions for a group of FPGAs. The trace and injection logic can be built into one or more of the FPGAs of an emulator. The host system can synthesize multiplexers to be mapped into the FPGAs. The multiplexers can be used by the trace and injection logic to inject interface signals into the DUT logic.

The host system creates bit files describing each partition of the DUT and the mapping of the partitions to the FPGAs. For partitions in which trace and injection logic are included, the bit files also describe the logic that is included. The bit files can include place and route information and design constraints. The host system stores the bit files and information describing which FPGAs are to emulate each component of the DUT (e.g., to which FPGAs each component is mapped).

Upon request, the host system transmits the bit files to the emulator. The host system signals the emulator to start the emulation of the DUT. During emulation of the DUT or at the end of the emulation, the host system receives emulation results from the emulator through the emulation connection. Emulation results are data and information generated by the emulator during the emulation of the DUT which include interface signals and states of interface signals that have been traced by the trace and injection logic of each FPGA. The host system can store the emulation results and/or transmits the emulation results to another processing system.

After emulation of the DUT, a circuit designer can request to debug a component of the DUT. If such a request is made, the circuit designer can specify a time period of the emulation to debug. The host system identifies which FPGAs are emulating the component using the stored information. The host system retrieves stored interface signals associated with the time period and traced by the trace and injection logic of each identified FPGA. The host system signals the emulator to re-emulate the identified FPGAs. The host system transmits the retrieved interface signals to the emulator to re-emulate the component for the specified time period. The trace and injection logic of each identified FPGA injects its respective interface signals received from the host system into the logic of the DUT mapped to the FPGA. In case of multiple re-emulations of an FPGA, merging the results produces a full debug view.

The host system receives, from the emulation system, signals traced by logic of the identified FPGAs during the re-emulation of the component. The host system stores the signals received from the emulator. The signals traced during the re-emulation can have a higher sampling rate than the sampling rate during the initial emulation. For example, in the initial emulation a traced signal can include a saved state of the component every X milliseconds. However, in the re-emulation the traced signal can include a saved state every Y milliseconds where Y is less than X. If the circuit designer requests to view a waveform of a signal traced during the re-emulation, the host system can retrieve the stored signal and display a plot of the signal. For example, the host system can generate a waveform of the signal. Afterwards, the circuit designer can request to re-emulate the same component for a different time period or to re-emulate another component.

A host system 1607 and/or the compiler 1610 may include sub-systems such as, but not limited to, a design synthesizer sub-system, a mapping sub-system, a run time sub-system, a results sub-system, a debug sub-system, a waveform sub-system, and a storage sub-system. The sub-systems can be structured and enabled as individual or multiple modules or two or more may be structured as a module. Together these sub-systems structure the emulator and monitor the emulation results.

The design synthesizer sub-system transforms the HDL that is representing a DUT 1605 into gate level logic. For a DUT that is to be emulated, the design synthesizer sub-system receives a description of the DUT. If the description of the DUT is fully or partially in HDL (e.g., RTL or other level of representation), the design synthesizer sub-system synthesizes the HDL of the DUT to create a gate-level netlist with a description of the DUT in terms of gate level logic.

The mapping sub-system partitions DUTs and maps the partitions into emulator FPGAs. The mapping sub-system partitions a DUT at the gate level into a number of partitions using the netlist of the DUT. For each partition, the mapping sub-system retrieves a gate level description of the trace and injection logic and adds the logic to the partition. As described above, the trace and injection logic included in a partition is used to trace signals exchanged via the interfaces of an FPGA to which the partition is mapped (trace interface signals). The trace and injection logic can be added to the DUT prior to the partitioning. For example, the trace and injection logic can be added by the design synthesizer sub-system prior to or after the synthesizing the HDL of the DUT.

In addition to including the trace and injection logic, the mapping sub-system can include additional tracing logic in a partition to trace the states of certain DUT components that are not traced by the trace and injection. The mapping sub-system can include the additional tracing logic in the DUT prior to the partitioning or in partitions after the partitioning. The design synthesizer sub-system can include the additional tracing logic in an HDL description of the DUT prior to synthesizing the HDL description.

The mapping sub-system maps each partition of the DUT to an FPGA of the emulator. For partitioning and mapping, the mapping sub-system uses design rules, design constraints (e.g., timing or logic constraints), and information about the emulator. For components of the DUT, the mapping sub-system stores information in the storage sub-system describing which FPGAs are to emulate each component.

Using the partitioning and the mapping, the mapping sub-system generates one or more bit files that describe the created partitions and the mapping of logic to each FPGA of the emulator. The bit files can include additional information such as constraints of the DUT and routing information of connections between FPGAs and connections within each FPGA. The mapping sub-system can generate a bit file for each partition of the DUT and can store the bit file in the storage sub-system. Upon request from a circuit designer, the mapping sub-system transmits the bit files to the emulator, and the emulator can use the bit files to structure the FPGAs to emulate the DUT.

If the emulator includes specialized ASICs that include the trace and injection logic, the mapping sub-system can generate a specific structure that connects the specialized ASICs to the DUT. In some examples, the mapping sub-system can save the information of the traced/injected signal and where the information is stored on the specialized ASIC.

The run time sub-system controls emulations performed by the emulator. The run time sub-system can cause the emulator to start or stop executing an emulation. Additionally, the run time sub-system can provide input signals and data to the emulator. The input signals can be provided directly to the emulator through the connection or indirectly through other input signal devices. For example, the host system can control an input signal device to provide the input signals to the emulator. The input signal device can be, for example, a test board (directly or through cables), signal generator, another emulator, or another host system.

The results sub-system processes emulation results generated by the emulator. During emulation and/or after completing the emulation, the results sub-system receives emulation results from the emulator generated during the emulation. The emulation results include signals traced during the emulation. Specifically, the emulation results include interface signals traced by the trace and injection logic emulated by each FPGA and can include signals traced by additional logic included in the DUT. Each traced signal can span multiple cycles of the emulation. A traced signal includes multiple states and each state is associated with a time of the emulation. The results sub-system stores the traced signals in the storage sub-system. For each stored signal, the results sub-system can store information indicating which FPGA generated the traced signal.

The debug sub-system allows circuit designers to debug DUT components. After the emulator has emulated a DUT and the results sub-system has received the interface signals traced by the trace and injection logic during the emulation, a circuit designer can request to debug a component of the DUT by re-emulating the component for a specific time period. In a request to debug a component, the circuit designer identifies the component and indicates a time period of the emulation to debug. The circuit designer's request can include a sampling rate that indicates how often states of debugged components should be saved by logic that traces signals.

The debug sub-system identifies one or more FPGAs of the emulator that are emulating the component using the information stored by the mapping sub-system in the storage sub-system. For each identified FPGA, the debug sub-system retrieves, from the storage sub-system, interface signals traced by the trace and injection logic of the FPGA during the time period indicated by the circuit designer. For example, the debug sub-system retrieves states traced by the trace and injection logic that are associated with the time period.

The debug sub-system transmits the retrieved interface signals to the emulator. The debug sub-system instructs the debug sub-system to use the identified FPGAs and for the trace and injection logic of each identified FPGA to inject its respective traced signals into logic of the FPGA to re-emulate the component for the requested time period. The debug sub-system can further transmit the sampling rate provided by the circuit designer to the emulator so that the tracing logic traces states at the proper intervals.

To debug the component, the emulator can use the FPGAs to which the component has been mapped. Additionally, the re-emulation of the component can be performed at any point specified by the circuit designer.

For an identified FPGA, the debug sub-system can transmit instructions to the emulator to load multiple emulator FPGAs with the same configuration of the identified FPGA. The debug sub-system additionally signals the emulator to use the multiple FPGAs in parallel. Each FPGA from the multiple FPGAs is used with a different time window of the interface signals to generate a larger time window in a shorter amount of time. For example, the identified FPGA can require an hour or more to use a certain amount of cycles. However, if multiple FPGAs have the same data and structure of the identified FPGA and each of these FPGAs runs a subset of the cycles, the emulator can require a few minutes for the FPGAs to collectively use all the cycles.

A circuit designer can identify a hierarchy or a list of DUT signals to re-emulate. To enable this, the debug sub-system determines the FPGA needed to emulate the hierarchy or list of signals, retrieves the necessary interface signals, and transmits the retrieved interface signals to the emulator for re-emulation. Thus, a circuit designer can identify any element (e.g., component, device, or signal) of the DUT to debug/re-emulate.

The waveform sub-system generates waveforms using the traced signals. If a circuit designer requests to view a waveform of a signal traced during an emulation run, the host system retrieves the signal from the storage sub-system. The waveform sub-system displays a plot of the signal. For one or more signals, when the signals are received from the emulator, the waveform sub-system can automatically generate the plots of the signals.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

What is claimed is:

1. A method for circuit equivalence processing, comprising:
receiving a circuit design including a plurality of subsystems, each of the plurality of subsystems being implemented using at least one field-programmable gate array (FPGA);
analyzing, via one or more processors, the plurality of subsystems for equivalence to identify at least two subsystems of the plurality of subsystems to be replaced with at least two replicated subsystems; and
generating a netlist for the circuit design including the at least two replicated subsystems.

2. The method of claim 1, wherein the at least two subsystems have different circuit structures and are identified to be equivalent based on logic of the at least two subsystems serving a common logic function.

3. The method of claim 1, wherein:
the at least two subsystems include at least a first subsystem and a second subsystem, at least one first circuit instance of the first subsystem being different than at least one second circuit instance of the second subsystem; and
identifying the at least two subsystems includes identifying whether the at least one first circuit instance and the at least one second circuit instance generate the same one or more outputs in response to one or more inputs.

4. The method of claim 1, wherein the analyzing of the plurality of subsystems for equivalence is performed using graph-isomorphism.

5. The method of claim 1, wherein the at least two subsystems are identified to be equivalent based on a circuit description associated with the at least two subsystems being the same.

6. The method of claim 1, wherein the at least two subsystems are identified to be equivalent by analyzing one or more inputs or one or more outputs of each subsystem of the at least two subsystems.

7. The method of claim 6, wherein the one or more inputs include multiple inputs, and wherein analyzing the multiple inputs includes identifying whether the multiple inputs are mutable.

8. The method of claim 7, wherein identifying whether the one or more inputs are mutable includes identifying whether an order of the multiple inputs can be changed without changing a function of the subsystem.

9. The method of claim 1, wherein the at least two subsystems includes at least a first subsystem and a second subsystem, the at least two subsystems being identified based on whether an entirety of the first subsystem is equivalent to a subset of the second subsystem.

10. The method of claim 9, wherein each of the at least two replicated subsystems replicates the second subsystem based on the entirety of the first subsystem being equivalent to the subset of the second subsystem.

11. The method of claim 10, wherein the at least two replicated subsystems include a first replicated subsystem to replace the first subsystem and a second replicated subsystem to replace the second subsystem, and wherein a circuit instance of the first replicated subsystem is deactivated.

12. The method of claim 1, wherein:
the at least two subsystems include at least a first subsystem and a second subsystem, a first circuit instance of the first subsystem being different than a second circuit instance of the second subsystem; and
each of the at least two replicated subsystems includes a multiplexer having a first input coupled to the first circuit instance and a second input coupled to the second circuit instance.

13. The method of claim 12, wherein:
the at least two replicated subsystems include a first replicated subsystem to replace the first subsystem and a second replicated subsystem to replace the second subsystem;
the multiplexer of the first replicated subsystem is configured to receive a first control signal to select the first circuit instance of the first subsystem; and
the multiplexer of the second replicated subsystem is configured to receive a second control signal to select the second circuit instance of the second subsystem.

14. A method for replicated subsystem generation, comprising:
receiving a circuit design including a plurality of subsystems, each of the plurality of subsystems being implemented using at least one field-programmable gate array (FPGA);
determining that at least two subsystems of the plurality of subsystems are not equivalent;
generating at least two replicated subsystems to replace the at least two subsystems based on the determination, each of the at least two replicated subsystems being configured to serve circuit functions of the at least two subsystems; and
generating a netlist for the circuit design including the at least two replicated subsystems.

15. The method of claim 14, wherein:
the at least two subsystems include at least a first subsystem and a second subsystem; and
an entirety of the first subsystem is equivalent to a subset of the second subsystem.

16. The method of claim 15, wherein each of the at least two replicated subsystems is generated to replicate the second subsystem based on the entirety of the first subsystem being equivalent to the subset of the second subsystem.

17. The method of claim 16, wherein the at least two replicated subsystems include a first replicated subsystem to replace the first subsystem and a second replicated subsystem to replace the second subsystem, and wherein a circuit instance of the first replicated subsystem is deactivated.

18. The method of claim 14, wherein:
the at least two subsystems include at least a first subsystem and a second subsystem, a first circuit instance of the first subsystem being different than a second circuit instance of the second subsystem; and
each of the at least two replicated subsystems includes a multiplexer having a first input coupled to the first circuit instance and a second input coupled to the second circuit instance.

19. The method of claim 18, wherein:
the at least two replicated subsystems include a first replicated subsystem to replace the first subsystem and a second replicated subsystem to replace the second subsystem;
the multiplexer of the first replicated subsystem is configured to receive a first control signal to select the first circuit instance of the first subsystem; and
the multiplexer of the second replicated subsystem is configured to receive a second control signal to select the second circuit instance of the second subsystem.

20. A system comprising:
a memory storing instructions; and
a processor, coupled with the memory and to execute the instructions, the instructions when executed cause the processor to:
receive a circuit design including a plurality of subsystems, each of the plurality of subsystems being implemented using at least one field-programmable gate array (FPGA);
analyze the plurality of subsystems for equivalence to identify at least two subsystems of the plurality of subsystems to be replaced with at least two replicated subsystems; and
generate a netlist for the circuit design including the at least two replicated subsystems.
